(19) United States
(12) Patent Application Publication
(10) Pub. No.: US 2017/0322495 A1
(43) Pub. Date: Nov. 9, 2017

(54) COMPOSITION FOR REMOVING PHOTORESIST AND METHOD FOR REMOVING PHOTORESIST USING THE SAME

(71) Applicant: UNIVERSITY-INDUSTRY FOUNDATION, YONSEI UNIVERSITY, Seoul (KR)

(72) Inventors: Sang Woo LIM, Seoul (KR); Eun Seok OH, Seoul (KR)

(21) Appl. No.: 15/393,586

(22) Filed: Dec. 29, 2016

(30) Foreign Application Priority Data
May 3, 2016 (KR) 10-2016-0054635
Sep. 8, 2016 (KR) 10-2016-0115533

(51) Int. Cl. G03F 7/42; H01L 21/027; B08B 3/08

(52) U.S. Cl. CPC G03F 7/426; B08B 3/08; H01L 21/0272

(57) ABSTRACT

Provided are a composition for removing a photoresist and a method for removing a photoresist using the same. According to the method, a high-dose ion implanted photoresist may be effectively removed without damage such as etching or oxidation of a semiconductor substrate.

### CROSS-REFERENCE TO RELATED APPLICATIONS

This application claims priority under 35 USC §119(a) of Korean Patent Applications Nos. 10-2016-0054635 filed on May 3, 2016 and 10-2016-0115533 filed on Sep. 8, 2016, the subject matter of which are hereby incorporated by references.

### BACKGROUND

### 1. Field of the Invention

The present invention relates to a composition for removing a photoresist and a method for removing a photoresist using the same.

The national research development project supporting the present invention is an industrial technology innovation project No. 10049099, [RCMS] Consortium of Semiconductor Advanced Research (COSAR)/Development of Total Front-End Cleaning Technologies for Ge and III-V Semiconductor Channel (3/5)/(Future Semiconductor device), funded by the Ministry of Trade, Industry and Energy, and supported by the University-Industry Foundation, Yonsei University, which is the lead agency.

### 2. Discussion of Related Art

In semiconductor technology, problems such as a short channel effect, tunneling current, and increased leakage current have occurred due to continued downscaling, and as semiconductor density increases and the downscaling of the technology progresses, the above-mentioned problems are becoming more serious. Also, semiconductors recently are being applied in smart home appliances, digital cameras with smart functions, etc., as well as high-performance portable devices, and due to the convergence of the functions of these devices, performance requirement and demands are explosively increasing, thereby further magnifying the problems.

One of the various methods to solve such problems is the use of III-V group semiconductor channels which are receiving attention as the next generation transistor materials due to high electron mobility. Due to the high mobility and low power consumption of the III-V group semiconductors, enhanced speed and improved characteristics of a device are expected. For this reason, globally, a variety of research and development are being conducted for achieving a semiconductor manufacturing technology that uses the material as channels.

To commercialize such III-V group semiconductor channels, it is necessary to remove a photoresist on a semiconductor channel. Meanwhile, a photoresist may be classified into G-line (436 nm), I-line (365 nm), KrF (248 nm), ArF (193 nm), and F2 (157 nm) according to a wavelength.

In a conventional transistor fabricating process, a sulfuric peroxide mixture (SPM) or ozone water is generally used to remove an ion-implanted photoresist on a silicon semiconductor. However, the method using SPM or ozone water causes etching and oxidation on a surface of a highly-integrated III-V group semiconductor, thereby deforming the semiconductor surface, and thus it is not appropriate as a method for removing a photoresist.

In another method for removing a photoresist, a high temperature photoresist removing process may cause deformation of a highly-integrated transistor. Also, a conventional photoresist method using an organic solvent has been used as a method for removing a bulk photoresist. Therefore, this method has a limit to be applied to a transistor process using a highly-integrated III-V group semiconductor.

For this reason, technology for removing a photoresist on the highly-integrated III-V group semiconductor without deformation of the surface thereof is expected to have great influence on the future development of a next generation transistor, and thus there is a demand for developing a method for removing a photoresist of a III-V group semiconductor at room temperature without using SPM or ozone water.

### PRIOR ART DOCUMENT

### Patent Document

(Patent Document 1) Korean Unexamined Patent Application Publication No. 10-2006-0131180.

### SUMMARY OF THE INVENTION

The present invention is directed to providing a composition for removing a photoresist, which may effectively remove a high-dose ion implanted photoresist, and minimize surface damage to a semiconductor substrate.

The present invention is also directed to providing a method for removing a photoresist by removing a photoresist within a short period of time at a relatively low temperature using the composition for removing a photoresist, which, thus, may not cause deformation of a transistor, may enhance the lifespan of equipment, and is suitable for mass-production.

To achieve the above-mentioned objectives, the present invention provides a composition for removing a photoresist, which comprises a first solvent having a molar volume of 70 cm³/mol or less and a second solvent having a Hansen relative energy difference from a photoresist of less than 1.05.

In addition, the present invention provides a method for removing a photoresist, which comprises reacting a semiconductor substrate on which a photoresist is formed with a composition comprising a first solvent having a molar volume of 70 cm³/mol or less and a second solvent having a Hansen relative energy difference from the photoresist of less than 1.05.

### BRIEF DESCRIPTION OF DRAWINGS

FIG. 1 schematically illustrates a method for removing a photoresist according to the present invention.

FIG. 2 schematically illustrates a process of removing a photoresist formed on a semiconductor surface having a trench structure.

FIGS. 3 to 6 illustrate removal of a photoresist from GaAs wafers according to Examples 1 to 4, where I is an optical microscope image, II is a scanning electron microscope (SEM) image, A is a GaAs wafer implanted with ions at a dose of 5×10¹³ ions/cm², B is a GaAs wafer implanted with ions at a dose of 5×10¹⁴ ions/cm², and C is a GaAs wafer implanted with ions at a dose of 5×10¹⁵ ions/cm².

FIGS. 7 to 10 are optical microscopy images illustrating removal of a photoresist from GaAs wafers according to Examples 5 to 8, where A is a GaAs wafer implanted with ions at a dose of 5×10¹³ ions/cm², B is a GaAs wafer implanted with ions at a dose of 5×10¹⁴ ions/cm², and C is a GaAs wafer implanted with ions at a dose of 5×10¹⁵ ions/cm².

FIGS. 11 to 14 illustrate the degree of the photoresist removal (percentage) according to removal time, which varies depending on an ion implantation dose in the process of removing a photoresist according to Examples 1 to 4.

FIG. 15 shows atomic force microscope (AFM) images for comparing changes in surface roughness of a GaAs wafer before and after a first solvent and/or a second solvent according to the present invention are (is) treated.

FIG. 16 shows optical microscope images illustrating the removal of a photoresist on GaAs wafers using a composition for removing a photoresist according to Examples 9 to 17. Here, a, b and c indicate the cases in which hydrochloric acid, fluoric acid and phosphoric acid are added to an acid compound, respectively, and 1, 3 and 5 indicate parts by volume of the acid compounds added to the composition for removing a photoresist.

FIG. 17 shows optical microscope images illustrating the removal of a photoresist on GaAs wafers according to temperatures of a composition for removing a photoresist according to Examples 9 to 17. Here, a, b and c indicate the cases in which hydrochloric acid, fluoric acid and phosphoric acid are added to an acid compound, respectively, and 30, 50, 70 and 90 indicate temperatures of the composition for removing a photoresist.

### DETAILED DESCRIPTION OF THE INVENTION

Hereinafter, the present invention will be described in further detail.

The present invention relates to a composition for removing a photoresist.

An SPM or ozone water generally used as a conventional photoresist removing solution induces etching and oxidation occurring on a semiconductor substrate, specifically, a highly-integrated III-V group semiconductor surface, allowing deformation of a semiconductor surface.

To solve the above-mentioned problem, the composition for removing a photoresist according to the present invention includes a solvent having a low molar volume, a solvent having high affinity to a photoresist and an acid compound, and thus a photoresist having a crust layer due to high-dose ion implantation can be effectively removed without damage to the surface of a semiconductor substrate.

Accordingly, the composition for removing a photoresist according to the present invention may include a first solvent having a molar volume of 70 cm³/mol or less and a second solvent having a Hansen relative energy difference from the photoresist of less than 1.05.

Specifically, the molar volume of the first solvent may be 67 cm³/mol or less, 65 cm³/mol or less, 20 to 62 cm³/mol or 25 to 61 cm³/mol, and more specifically, 30 to 60 cm³/mol.

As described above, since the composition for removing a photoresist according to the present invention includes the first solvent having a relatively low molar volume in the above range, the solvent may be easily permeated into the photoresist to effectively make the photoresist swell.

Also, the photoresist may be soluble in the first solvent to an extent. That is, while the first solvent may be permeated into a crust layer of the photoresist to mainly make the photoresist swell, a part of the photoresist may also be removed due to the solubility.

In one embodiment, the first solvent may have a Hansen relative energy difference from the photoresist of less than 1.3, 1.25 or 1.2. The lowest value of the Hansen relative energy difference may be, for example, 1.05 or more. The definition of Hansen relative energy will be described.

The first solvent may be any one of the known solvents meeting suitable molar volume and solubility for achieving the above-mentioned objectives, without limitation.

In one embodiment, the first solvent may be one or more selected from the group consisting of acetonitrile, formamide, nitromethane and monoethanolamine and may be a suitable solvent selected from the above types by considering molar volume and solubility.

The term “Hansen relative energy difference” is defined by General Formula 1, and refers to affinity of a solvent with respect to a photoresist polymer.

Rₐ/R₀ [General Formula 1]

In General Formula 1, R₀ refers to the interaction radius of a photoresist, and Rₐ refers to the distance in Hansen space of Hansen parameters calculated by General Formula 2.

[4(δ_{d2}−δ_{d1})²+(δₚ₂−δₚ₁)²+(δₕ₂−δₕ₁)²]^{1/2} [General Formula 2]

In General Formula 2, δ_{d} is energy generated by dispersion force between molecules, δₚ is energy generated by a dipolar intermolecular force between molecules, and δₕ is energy generated by a hydrogen bond between molecules, and the unit of the parameters δ_{d}, δₚ and δₕ is, for example, MPa^{0.5}.

Conventionally, if a distance between HSP values of two materials is Rₐ, when Rₐ of a material is higher than 1 with respect to the characteristic interaction radius R₀, it is determined that the material is not dissolved, and when Rₐ with respect to R₀ is smaller than 1, it is determined that the material is dissolved. Therefore, as the composition for removing a photoresist of the present invention includes the second solvent having a Rₐ value of less than 1.05 with respect to the characteristic interaction radius R₀, the photoresist may be effectively removed.

In another exemplary embodiment, the second solvent may have a Hansen relative energy difference from the photoresist of less than 1.0, 0.90 or 0.08. The lower limit of the Hansen relative energy difference may be, but is not particularly limited to, for example, more than 0.1 or 0.2.

When the second solvent has a Hansen relative energy difference from the photoresist in the above range, the second solvent may have high affinity to the photoresist, and thus the photoresist may be easily removed by dissolving the photoresist swelled due to the second solvent.

The second solvent may also have a specific molar volume. The second solvent may have a relatively high molar volume compared to the first solvent. However, with an excessively high molar volume, the second solvent may not be permeated into the photoresist layer, and therefore a suitable range of molar volume is needed.

In one embodiment, the second solvent may have a molar volume in the range of 60 cm³/mol to 120 cm³/mol. In another embodiment, the molar volume of the second solvent may be in the range of 70 cm³/mol to 110 cm³/mol.

The second solvent may be any one meeting the above-mentioned physical properties, without limitation, and for example, the second solvent may be any one selected from the group consisting of 2-pyrrolidone, dimethylsulfoxide, benzylalcohol and propylenecarbonate and may be a suitable solvent selected from the above types by considering solubility of the photoresist and molar volume.

The composition for removing a photoresist of the present invention may be a two-liquid type composition, which is divided into a first solution including a first solvent and a second solution including a second solvent. The present invention also includes a one-liquid type composition. However, it was confirmed that treatment of a semiconductor substrate with the second solvent after treatment with the first solvent is more effective in removing a photoresist. Also, the composition for removing a photoresist of the present invention may further include an acid compound. The acid compound may be any one that can facilitate the removal of the photoresist and does not cause deformation of the semiconductor substrate, without limitation. For example, the acid compound may be one or more selected from the group consisting of fluoric acid (HF), hydrochloric acid (HCl), phosphoric acid (H₃PO₄), nitric acid (HNO₃), sulfuric acid (H₂SO₄), oxalic acid and acetic acid and may specifically be fluoric acid (HF).

The composition for removing a photoresist of the present invention may further include a base compound or may include a base compound instead of an acid compound. Here, the base compound may be tetramethylammonium hydroxide (TMAH).

The present invention showed that, even when the composition including an acid compound is a one-liquid type composition, photoresist removal efficiency is not decreased.

Accordingly, the composition for removing a photoresist of the present invention may be prepared in two types.

(1) A two-liquid type composition which is divided into a first solution including a first solvent and a second solution including a second solvent

(2) A one-liquid type composition including a first solvent, a second solvent and an acid compound

In the present invention, contents of components of the composition are as follows.

The composition for removing a photoresist of the present invention may include 10 to 60 parts by volume of a first solvent and 20 to 70 parts by volume of a second solvent. In some cases, the composition for removing a photoresist of the present invention may further include 0.1 to 10 parts by volume of an acid compound.

Specifically, the content of the first solvent may be 15 to 55 parts by volume, 20 to 50 parts by volume, 25 to 45 parts by volume or 30 to 40 parts by volume. In the composition for removing a photoresist, when the content of the first solvent is in the above range, the first solvent is permeated into a crust layer of a photoresist to easily make the photoresist swell.

Also, the content of the second solvent may be, specifically, 25 to 68 parts by volume, 30 to 65 parts by volume, 35 to 65 parts by volume, or 50 to 60 parts by volume. In the composition for removing a photoresist, when the content of the second solvent is in the above range, the second solvent is permeated into the crust layer of the photoresist, and thus the swollen photoresist swollen is easily removed.

Moreover, the content of the acid compound may be specifically 0.1 to 10 parts by volume, 0.3 to 8 parts by volume, 0.5 to 5 parts by volume, 0.8 to 3 parts by volume, or 1 part by volume. When the composition for removing a photoresist includes the acid compound in the above range, photoresist residue and the crust layer thereof may be easily removed without deformation of the semiconductor substrate.

The term “parts by volume” used herein refers to a volume ratio between components.

The present invention relates to a method for removing a photoresist.

A method using an SPM or ozone water or process of removing a photoresist at high temperature, which is generally used in a conventional method for removing a photoresist, causes deformation on a semiconductor surface due to etching and oxidation occurring on a semiconductor substrate, and specifically, a highly-integrated III-V group semiconductor surface. The present invention is provided to solve the above problem, and the method for removing a photoresist according to the present invention may effectively remove a photoresist having a crust layer due to high dose ion implantation, without damage to the surface of a semiconductor substrate, by removing the photoresist through a simple procedure of reacting the semiconductor substrate on which the photoresist is formed with a composition for removing a photoresist including a solvent with a low molar volume, a solvent with a high affinity to a photoresist, and an acid compound.

By the method of removing a photoresist according to the present invention, a high-dose ion implanted photoresist may be effectively removed, and since the photoresist removal process may be performed both at room temperature and high temperature, deformation occurring at highly-integrated transistors due to high temperature may be prevented. Also, it may be relatively easy to reuse a solvent used in the process by minimizing loss of the solvent due to evaporation, and a load to equipment may be reduced to improve a lifespan of the equipment.

The method for removing a photoresist according to the present invention includes reacting a composition including a first solvent having a molar volume of 70 cm³/mol or less and a second solvent having a Hansen relative energy difference from the photoresist of less than 1.05 with a semiconductor substrate on which a photoresist is formed.

Here, the step of reacting the composition with the semiconductor substrate may include immersing the semiconductor substrate on which the photoresist is formed in the composition, spraying the composition on the semiconductor substrate on which the photoresist is formed, and flowing the composition onto the semiconductor substrate on which the photoresist is formed. For example, in the step of reacting the composition with the semiconductor substrate, the semiconductor substrate on which the photoresist is formed may be immersed in the composition to perform the reaction. Specifically, the composition may be a composition for removing a photoresist.

In one example, the method for removing a photoresist according to the present invention includes immersing a semiconductor substrate on which a photoresist is formed in a first solution including a first solvent having a molar volume of 70 cm³/mol or less to make the photoresist swell and immersing the semiconductor substrate on which the swollen photoresist is formed in a second solution including a second solvent having a Hansen relative energy difference from the photoresist of less than 1.05 to remove the photoresist.

In the making the photoresist of the semiconductor substrate on which the photoresist is formed according to the present invention swell, a gel layer in the photoresist may be formed by permeating the solvent having a lower molar volume into a bulk region in the photoresist having a crust by implanting a high dose of ions.

Since the first solution according to the present invention includes the first solvent having a relatively low molar volume in the above-mentioned range, it may be easily permeated into the photoresist to effectively make the photoresist swell. As the crust of photoresist is partially cracked due to the swollen photoresist, a space into which the second solution may be permeated is created.

The photoresist may have specific solubility in the first solvent. That is, while the first solvent mainly serves to make the photoresist swell by being permeated into the crust layer of the photoresist, a part of the photoresist may also be removed due to the solubility.

In another embodiment, the method for removing a photoresist according to the present invention may remove the photoresist by reacting a semiconductor substrate on which the photoresist is formed with a composition including a first solvent having a molar volume of 70 cm³/mol or less, a second solvent having a Hansen relative energy difference from the photoresist of less than 1.05, and an acid compound.

The content of the first solvent may be 10 to 60 parts by volume, and specifically, 15 to 55 parts by volume, 20 to 50 parts by volume, 25 to 45 parts by volume, or 30 to 40 parts by volume. When the content of the first solvent in the composition for removing a photoresist is in the above-mentioned range, even though the photoresist removal is performed within a relatively low temperature range, the first solvent is easily permeated into the crust layer of the photoresist and thus easily making the photoresist swell.

Also, the content of the second solvent may be 20 to 70 parts by volume, and specifically, 25 to 65 parts by volume, 30 to 60 parts by volume, 35 to 55 parts by volume, or 40 to 50 parts by volume. When the content of the second solvent in the composition for removing a photoresist is in the above-mentioned range, even though the photoresist removal is performed within a relatively low temperature range, the solvent may be permeated into the crust layer of the photoresist and dissolve the photoresist swollen thereby for easy removal and thus prevent deformation of the highly-integrated semiconductor substrate.

Further, the content of the acid compound may be 0.1 to 10 parts by volume, and specifically, 0.2 to 10 parts by volume, 0.3 to 10 parts by volume, 0.5 to 5 parts by volume, or 1 to 3 parts by volume. When the composition for removing a photoresist includes the acid compound in the above content range, photoresist residue and the crust layer of the photoresist may be easily removed without deformation of the semiconductor substrate.

In the method for removing a photoresist according to the present invention, the molar volume of the first solvent may be in the range of 67 cm³/mol or less, 65 cm³/mol or less, 20 to 62 cm³/mol, or 25 to 61 cm³/mol, and more specifically, 30 to 60 cm³/mol. As the composition for removing a photoresist according to the present invention includes the first solvent having a relatively lower molar volume in the above range, in the removal of the photoresist, the first solvent may be easily permeated into the photoresist to effectively make the photoresist swell. Also, in the first solvent, the photoresist may have specific solubility. That is, the first solvent mainly serves to make the photoresist swell by being permeated into the crust layer of the photoresist, and a part of the photoresist may also be removed due to the solubility.

In one embodiment, the first solvent may have a Hansen relative energy difference from the photoresist of less than 1.3, 1.25 or 1.2. The lowest value of the Hansen relative energy difference may be, for example, 1.05 or more. The definition of Hansen relative energy will be described.

The first solvent may be any one of the known solvents meeting suitable molar volume and solubility for achieving the above-mentioned objectives, without limitation.

In one embodiment, the first solvent may be one or more selected from the group consisting of acetonitrile, formamide, nitromethane and monoethanolamine, and may be a suitable solvent selected from the above types by considering the molar volume and the solubility.

The term “Hansen relative energy difference” is defined by General Formula 1 below, and refers to the affinity of a solvent with respect to a photoresist polymer.

Rₐ/R₀ [General Formula 1]

In General Formula 1, R₀ refers to the interaction radius of a photoresist, and Rₐ refers to the distance in Hansen space of Hansen parameters calculated by General Formula 2.

[4(δ_{d2}−δ_{d1})²+(δₚ₂−δₚ₁)²+(δₕ₂−δₕ₁)²]^{1/2} [General Formula 2]

In General Formula 2, δ_{d} is energy generated by dispersion force between molecules, δₚ is energy generated by a dipolar intermolecular force between molecules, and δₕ is energy generated by a hydrogen bond between molecules, and the unit of the parameters δ_{d}, δₚ and δₕ is, for example, MPa^{0.5}.

Conventionally, if a distance between HSP values of two materials is put as Rₐ, when Rₐ with respect to the characteristic interaction radius R₀ of a material is higher than 1, it is determined that the material is not dissolved, and when Rₐ with respect to R₀ is smaller than 1, it is determined that the material is dissolved. Therefore, as the composition for removing a photoresist of the present invention includes a second solvent having the Rₐ value of less than 1.05 with respect to the characteristic interaction radius R₀, a photoresist may be effectively removed.

In the method for removing a photoresist according to the present invention, the second solvent may be a Hansen relative energy difference from the photoresist of less than 1.0, 0.90 or 0.08. The lower limit of the Hansen relative energy difference may be, but is not particularly limited to, for example, more than 0.1 or 0.2.

When the second solvent has the Hansen relative energy difference from the photoresist in the above range, the second solvent may have high affinity to the photoresist, and thus the photoresist may be easily removed by dissolving the photoresist swelled due the second solvent.

The second solvent may also have a predetermined molar volume. The second solvent may have a relatively high molar volume compared to the first solvent. However, when having an excessively high molar volume, the second solvent may not be permeated into the photoresist layer, and therefore a suitable range of molar volume has to be achieved.

In one embodiment, the second solvent may have a molar volume in the range of 60 cm³/mol to 120 cm³/mol. In another embodiment, the molar volume of the second solvent may be in the range of 70 cm³/mol to 110 cm³/mol.

The second solvent may be any one meeting the above-mentioned physical properties, without limitation, and for example, the second solvent may be any one selected from the group consisting of 2-pyrrolidone, dimethylsulfoxide, benzylalcohol and propylenecarbonate, and may be a suitable one selected from the above kinds by considering the solubility of the photoresist and the molar volume.

In the present invention, the acid compound may be any one that can facilitate the removal of a photoresist and does not cause deformation of the semiconductor substrate, without limitation. For example, the acid compound may be one or more selected from the group consisting of fluoric acid (HF), hydrochloric acid (HCl), phosphoric acid (H₃PO₄), tetramethylammoniumhydroxide (TMAT), nitric acid (HNO₃), sulfuric acid (H₂SO₄), oxalic acid) and acetic acid, and specifically, fluoric acid (HF).

In the present invention, the semiconductor substrate may be any wafer used in a general semiconductor process, without limitation.

In one embodiment, the semiconductor substrate according to the present invention may be a III-V group semiconductor substrate.

Specifically, the III-V group semiconductor substrate may be formed of, for example, GaAs, GaP, InSb or InAs, and in the present invention, the semiconductor substrate may be a gallium arsenide (GaAs) substrate. The method for removing a photoresist according to the present invention may minimize deformation occurring on the surface of the highly-integrated semiconductor substrate formed of, for example, a III-V group compound, by performing a wet removing method of reacting the substrate with a composition comprising a first solution, a second solution and an acid compound.

In another embodiment, the semiconductor substrate according to the present invention may be a germanium (Ge)-containing semiconductor substrate.

In addition, the semiconductor substrate may have a surface patterned in a specific structure. The patterned structure may be, but is not particularly limited to, for example, a trench structure. The width or depth of the trench structure is known in the art.

According to the method for removing a photoresist of the present invention, surface damage to the semiconductor substrate may be minimized, and thus surface roughness difference between before and after the removal of the photoresist may be minimized.

In one embodiment, the semiconductor substrate of the present invention may have a difference in root-mean-square surface roughness (Rᵣₘₛ) of 0.1 nm or less between before and after the reaction with the composition for removing a photoresist. In another embodiment, the difference in root-mean-square surface roughness (Rᵣₘₛ) between before and after the reaction with the composition for removing a photoresist may be 0.05 nm or less, 0.04 nm or less, 0.03 nm or less, or 0.02 nm or less. The low root-mean-square surface roughness (Rims) means that the surface is less damaged commensurate with the root-mean-square surface roughness, and the lower limit may be, but is not particularly limited to, for example, 0.0001 nm or more or 0.001 nm or more. Since a semiconductor substrate going through the photoresist removal meets the surface roughness difference in the above range before and after the removal, it can be seen that the removal of the photoresist is well performed without damage to the semiconductor substrate.

Also, the semiconductor substrate according to the present invention may have a surface roughness of 0.5 nm or less, 0.4 nm or less, or 0.3 nm or less, which is measured after the reaction with the composition for removing a photoresist.

The method for removing a photoresist of the present invention may have excellent photoresist removal efficiency despite high-dose ion implantation.

In one embodiment, ions may be implanted into the photoresist according to the present invention at a dose of 5×10¹² to 5×10¹⁷ ions/cm². In another embodiment, the dose of the ions implanted into the photoresist may be in the range of 5×10¹³ to 5×10¹⁷ ions/cm² or 5×10¹⁴ to 5×10¹⁷ ions/cm².

In one embodiment, the method for removing a photoresist according to the present invention may further include a cleaning step after the photoresist removal. The cleaning step may be performed to prevent oxidation on the surface of the semiconductor substrate.

A cleaning solution that can be used in the cleaning step is not particularly limited as long as it is conventionally used in cleaning of the semiconductor substrate and may be, for example, a cleaning solution including an alcohol. Specific examples of the cleaning solution including an alcohol may include cleaning solutions such as isopropyl alcohol, methanol, ethanol, etc., and the cleaning solution may be a mixed solution of isopropyl alcohol, HF and deionized water, a mixed solution of methanol, HF and deionized water, or a mixed solution of ethanol, HF and deionized water. Specifically, in the present invention, the cleaning solution may be isopropyl alcohol.

For the cleaning step of the present invention, the photoresist-removed semiconductor substrate may be dipped in the cleaning solution, and the dipping may be performed for 5 to 100 seconds, 10 to 80 seconds, 15 to 70 seconds, 18 to 65 seconds, 20 to 60 seconds, 25 to 50 seconds, or 30 seconds. When the semiconductor substrate is dipped for the above range of time for cleaning, the substrate may be effectively cleaned without etching or oxidation of the semiconductor substrate.

In the present invention, after the cleaning step, the semiconductor substrate may be dried using a conventional method and, specifically, dried under N₂ flow.

In one embodiment, the method for removing a photoresist according to the present invention may be performed within 5 to 30 minutes. That is, the time of dipping the photoresist-formed semiconductor substrate in the composition for removing a photoresist according to the present invention may be 8 to 28 minutes, 10 to 25 minutes, 12 to 23 minutes or 15 to 20 minutes. When removal of a photoresist is performed within the above range of time, the photoresist may be effectively removed without etching or oxidation of the semiconductor substrate.

Also, the method for removing a photoresist of the present invention may be performed within a temperature range of 20 to 90° C. Specifically, the temperature range may be temperatures of the composition for removing a photoresist, for example, 20 to 85° C., 25 to 80° C., 28 to 70° C., 30 to 70° C., 30 to 65° C., or 30 to 50° C. In the present invention, as the photoresist is removed in a relatively low temperature range mentioned above, evaporation of the cleaning solution may be prevented, thus it is easy to reuse the solution, and deformation of the highly-integrated semiconductor substrate may be prevented, thereby improvement in performance of the semiconductor substrate may be expected.

The present invention provides a semiconductor substrate from which a photoresist is removed by the method for removing a photoresist. The semiconductor substrate of the present invention may have a root-mean-square surface roughness (Rᵣₘₛ) difference of 0.1 nm or less between before and after the reaction with the composition for removing a photoresist. In another embodiment, the root-mean-square surface roughness (Rᵣₘₛ) difference between before and after the reaction with the composition for removing a photoresist may be 0.05 nm or less, 0.04 nm or less, 0.03 nm or less, or 0.02 nm or less. The low root-mean-square surface roughness (Rᵣₘₛ) means that the surface is less damaged commensurate with the root-mean-square surface roughness (Rᵣₘₛ), and the lower limit may be, but is not particularly limited to, for example, 0.0001 nm or more or 0.001 nm or more. Since a semiconductor substrate going through the photoresist removal meets the above range of surface roughness difference before and after the removal, it can be seen that the removal of the photoresist is well performed without damage to the semiconductor substrate.

Also, the semiconductor substrate according to the present invention may have a surface roughness of 0.5 nm or less, 0.4 nm or less, or 0.3 nm or less.

### EXAMPLES

Hereinafter, the present invention will be described in further detail with reference to examples according to the present invention, but the scope of the present invention is not limited to the examples provided below.

### Example 1: Removal of Photoresist from Semiconductor Substrate Using Acetonitrile and Dimethylsulfoxide

(1) Step of Forming Photoresist

ArF photoresist (DHA-HA150, Dongjin Semichem Co., Ltd) was applied to coat a 4-inch GaAs(100) wafer as a semiconductor substrate at 1000 rpm for 30 seconds to have a thickness of 300 nm, and then annealed at 110° C. for 80 seconds. Afterward, P ions were implanted using a medium current ion implanter (E220, Varian) at 70 keV and a pressure of 10⁻⁶ Pa under each of condition A (5×10¹³ ions/cm²⁻), condition B (5×10¹⁴ ions/cm²) and condition C (5×10¹⁵ ions/cm²).

(2) Step of Removing Photoresist

The ArF photoresist-coated GaAs wafer was dipped in a first solution, acetonitrile (CH₃CN, ≧99.8%, Sigma-Aldrich) at 30° C. The molar volume of the acetonitrile was 52.6 cm³/mol. Then, the GaAs wafer was dipped in a second solution, dimethylsulfoxide. The basic value of the photoresist with respect to the dimethylsulfoxide, that is, Rₐ/R₀ of PMMA was 0.755. Here, the first solution and the second solution were maintained at a temperature of 30° C. Finally, the GaAs wafer was dipped in isopropylalcohol (C₃H₈O, IPA, ≧99.8%, Daejung Chemicals and Metals Co., Ltd) for 30 seconds for cleaning and dried under N₂ flow.

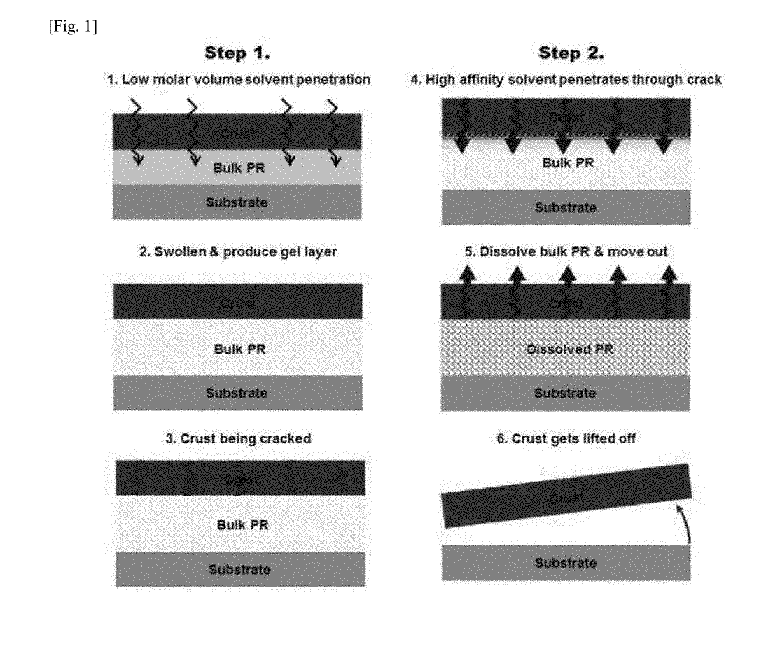

FIG. 1 schematically illustrates a process of removing a photoresist performed in two steps of dipping a substrate in a first solution and a second solution. Referring to FIG. 1, in Step 1, first, the first solvent having a low molar volume passed through a photoresist crust (1) and made a photoresist (Burk PR) swell (2), and then the crust was cracked to create a gap (3). Subsequently, in Step 2, the second solvent having affinity to a photoresist is permeated into the gap in the crust (4) to remove the photoresist by dissolving (5), and the crust was exfoliated (5), thereby removing the photoresist without deformation of and damage to the semiconductor substrate.

### Example 2: Removal of Photoresist from Semiconductor Substrate Using Nitromethane and Dimethylsulfoxide

Photoresist removal was performed by the same method as described in Example 1, except that, instead of acetonitrile as a first solution, nitromethane (CH₃NO₂, ≧95.0%, Sigma-Aldrich) having a molar volume of 54.3 cm³/mol was used in the photoresist removal.

### Example 3: Removal of Photoresist from Semiconductor Substrate Using Formamide and Dimethylsulfoxide

Photoresist removal was performed by the same method as described in Example 1, except that, instead of acetonitrile as a first solution, formamide (HCONH₂, ≧99.0%, Sigma-Aldrich) having a molar volume of 39.8 cm³/mol was used in the photoresist removal.

### Example 4: Removal of Photoresist from Semiconductor Substrate Using Monoethanolamine and Dimethylsulfoxide

Photoresist removal was performed by the same method as described in Example 1, except that, instead of acetonitrile as a first solution, monoethanolamine (NH₂CH₂CH₂OH, MEA, ≧99.0%, Sigma-Aldrich) having a molar volume of 59.8 cm³/mol was used in the photoresist removal.

Hereinafter, Examples 5 to 8 illustrate removal of a photoresist on a semiconductor substrate patterned in a trench structure.

### Example 5: Removal of Photoresist from Semiconductor Substrate Patterned in a Trench Structure Using Acetonitrile and Dimethylsulfoxide

(1) Step of Manufacturing Semiconductor Substrate Patterned in Trench Structure

A GaAs wafer coated with an I-line photoresist to a thickness of 1 μm was exposed to an I-line (365 nm) light source using a stepper (Nikon i11D). The exposed photoresist was developed in a DNS SK-200 Coater/Developer. The width and depth of the developed photoresist pattern were 500 nm. Subsequently, using an inductively-coupled plasma (ICP) etcher (multiplexer ICP, STS), the GaAs wafer was dry-etched to have a width of 550 nm and a depth of 500 nm under conditions including BCl₃/N₂ etch gas and a pressure of 0.667 Pa. Afterward, the GaAs wafer was dipped in dimethylsulfoxide at 150° C. for 20 minutes for removing the I-line photoresist and dipped in isopropylalcohol for 30 seconds for cleaning, thereby manufacturing the GaAs wafer patterned in a trench structure.

(2) Step of Forming Photoresist

A KrF photoresist (DWK-500, Dongwoo Fine-Chem) was applied to coat the GaAs wafer patterned in a trench structure at 2900 rpm for 60 seconds to have a thickness of 900 nm. Subsequently, P ions were implanted using a medium current ion implanter (E220, Varian) at 70 keV and a pressure of 10⁻⁶ Pa according to condition A (5×10¹³ ions/cm²), condition B (5×10¹⁴ ions/cm²) and condition C (5×10¹⁵ ions/cm²).

(3) Step of Removing Photoresist

The KrF photoresist-coated GaAs wafer was dipped in a first solution, acetonitrile (CH₃CN, ≧99.8%, Sigma-Aldrich) at 30° C. Then, the GaAs wafer was dipped in a second solution, dimethylsulfoxide. Here, the first solution and the second solution were maintained at 30° C. Finally, the GaAs wafer was dipped in isopropylalcohol (C₃H₈O, IPA, ≧99.8%, Daejung Chemicals and Metals Co., Ltd) for 30 seconds for cleaning and dried under N₂ flow.

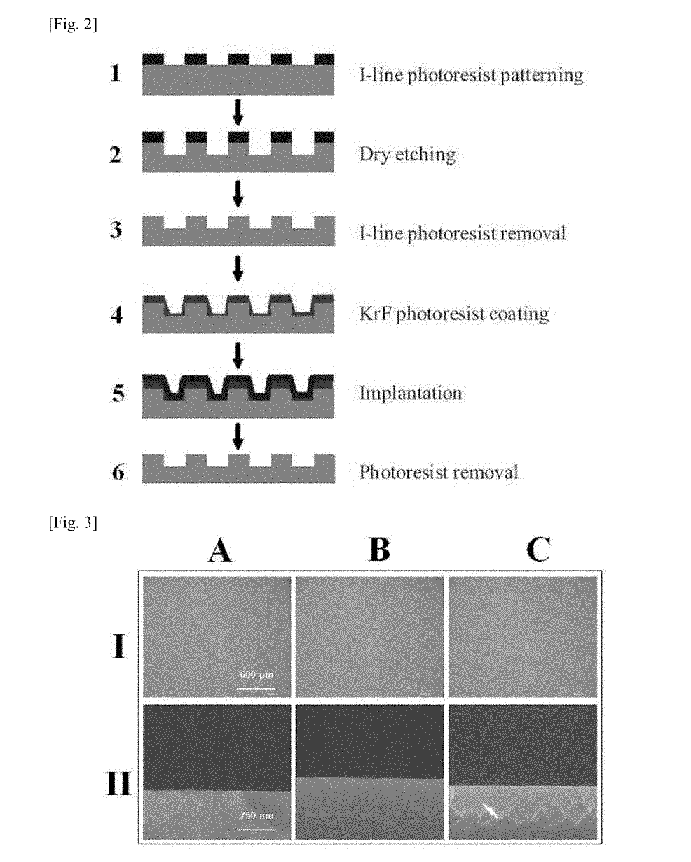

FIG. 2 schematically illustrates the removal of a photoresist after the semiconductor substrate is formed in a trench structure according to Example 5. Referring to FIG. 2, an I-line photoresist pattern was formed on a semiconductor substrate (1) and dry-etched (2), and the I-line photoresist was removed (3). Afterward, a KrF photoresist was applied (4), ions were implanted (5), and the photoresist was removed (6).

### Example 6: Removal of Photoresist from Semiconductor Substrate Patterned in Trench Structure Using Nitromethane and Dimethylsulfoxide

Photoresist removal was performed by the same method as described in Example 5, except that, instead of acetonitrile as a first solution, nitromethane (CH₃NO₂, ≧95.0%, Sigma-Aldrich) was used in the removal of a photoresist.

### Example 7: Removal of Photoresist from Semiconductor Substrate Patterned in Trench Structure Using Formamide and Dimethylsulfoxide

Photoresist removal was performed by the same method as described in Example 5, except that, instead of acetonitrile as a first solution, formamide (HCONH₂, ≧99.0%, Sigma-Aldrich) having a molar volume of 39.8 cm³/mol was used in the photoresist removal.

### Example 8: Removal of Photoresist from Semiconductor Substrate Patterned in Trench Structure Using Monoethanolamine and Dimethylsulfoxide

Photoresist removal was performed by the same method as described in Example 5, except that, instead of acetonitrile as a first solution, monoethanolamine (NH₂CH₂CH₂OH, MEA, ≧99.0%, Sigma-Aldrich) having a molar volume of 59.8 cm³/mol was used in the photoresist removal.

### Experimental Example 1: Examination of Optical Microscope and SEM Images According to Dose of Ion Implantation

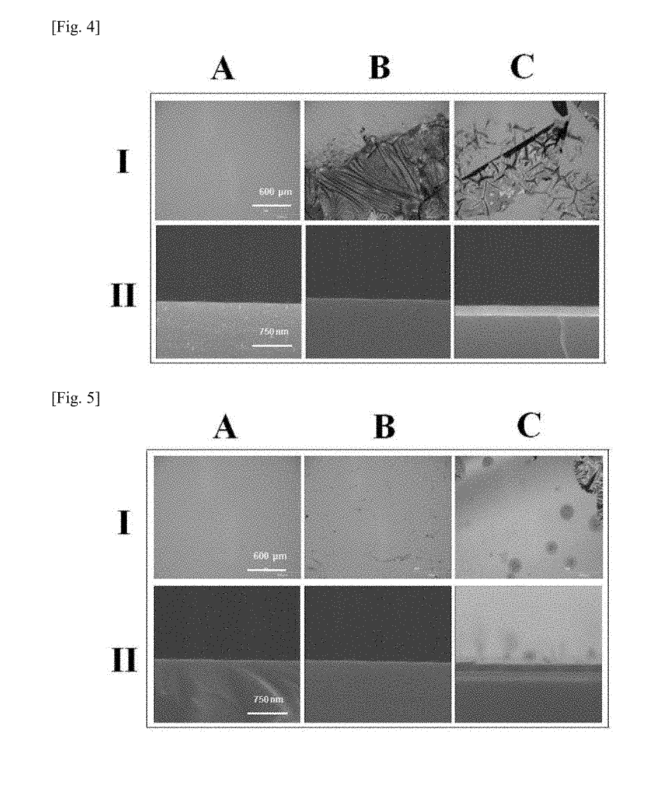

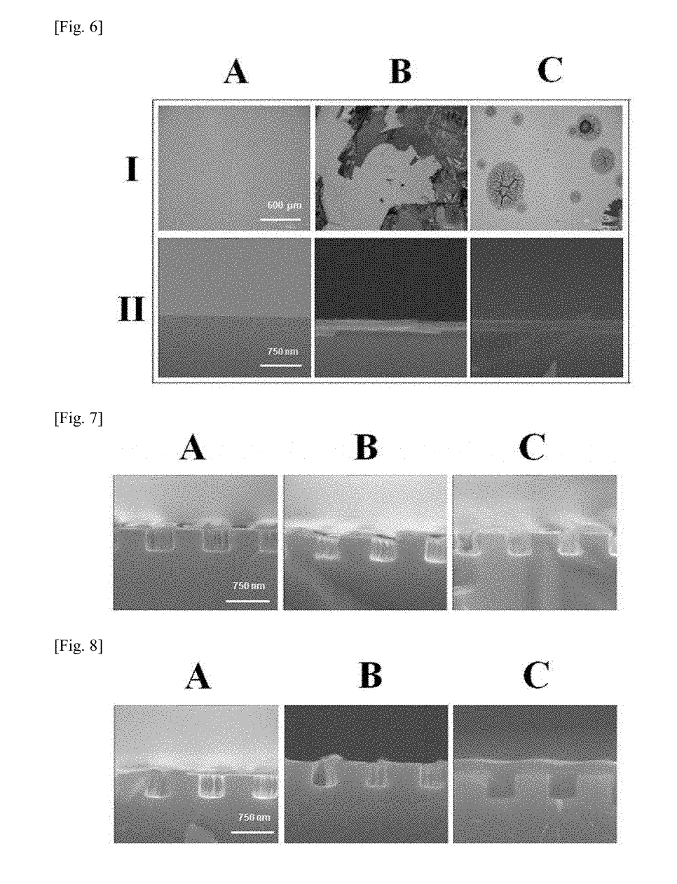

GaAs wafers from which a photoresist have been removed by being dipped in each of a first solution and a second solution for 15 minutes according to Examples 1 to 8 were observed by an optimal microscope and SEM. The results are shown in FIGS. 3 to 10, where A indicates a GaAs wafer having a photoresist implanted with ions at a dose of 5×10¹³ ions/cm², B indicates a GaAs wafer having a photoresist implanted with ions at a dose of 5×10¹⁴ ions/cm², and C indicates a GaAs wafer having a photoresist implanted with ions at a dose of 5×10¹⁵. Also, in FIGS. 3 to 6, I shows optical microscope images, and II shows SEM images.

As shown in FIGS. 3 to 10, when the ion implantation dose meets conditions A, B and C, photoresist removal efficiency may vary, and it can be seen that the most preferable first solvent is acetonitrile, and the most preferable second solvent is dimethylsulfoxide.

### Experimental Example 2: Results According to Ion Implantation Dose and Photoresist Removal Time

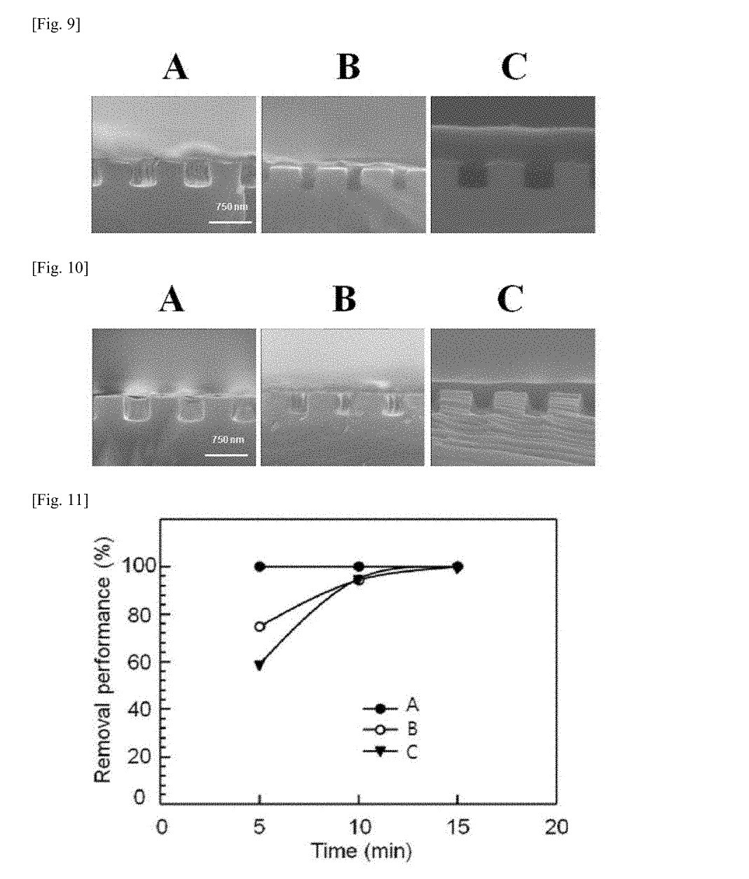

The extent of photoresist removal on GaAs wafers from which a photoresist had been removed by being dipped in each of a first solution and a second solution for 15 minutes, 10 minutes, 15 minutes and 30 minutes according to Examples 1 to 4, respectively, were expressed in percentages. The results are shown in FIGS. 11 to 14, where A is a GaAs wafer having a photoresist implanted with ions at a dose of 5×10¹³ ions/cm², B is a GaAs wafer having a photoresist implanted with ions at a dose of 5×10¹⁴ ions/cm², and C is a GaAs wafer having a photoresist implanted with ions at a dose of 5×10¹⁵.

As shown in FIGS. 11 to 14, when the photoresist is removed using acetonitrile as the first solvent and dimethylsulfoxide as the second solvent, it was confirmed that the photoresist may be 100% removed for a short period of time, such as 15 minutes, regardless of an ion implantation dose, and therefore it was seen that acetonitrile is most preferable as the first solvent, and dimethylsulfoxide is most preferable as the second solvent.

### Experimental Example 3: Measurement of Surface Roughness

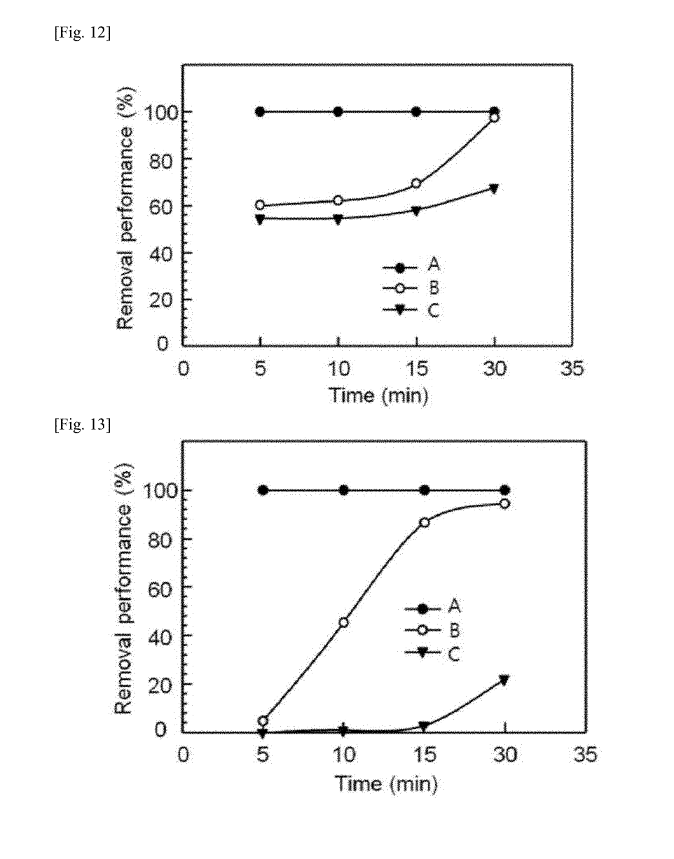

To confirm that the solutions used in individual steps described in Examples 1 and 5 do not damage a semiconductor substrate, surface roughness was evaluated after a GaAs wafer was not treated at all (a), dipped in acetonitrile for 15 minutes (b), dipped in dimethylsulfoxide for 15 minutes (c), and dipped in acetonitrile and then dimethylsulfoxide (d). The results are also shown with atomic force microscope (AFM) images in FIG. 15.

Referring to FIG. 15, it can be seen that a difference in surface roughness between the GaAs wafers which is not treated with a solvent according to the present invention (a) and dipped in acetonitrile and then dimethylsulfoxide (d) is the lowest. Thus, it was confirmed that the method for removing a photoresist according to the present invention can effectively remove a photoresist without deformation of or damage to a highly-integrated semiconductor surface.

### Examples 9 to 11

On the basis of 100 parts by volume of the composition for removing a photoresist, 40 parts by volume of acetonitrile (CH₃CN, ≧99.8%, Sigma-Aldrich) as a first solvent was mixed with 60 parts by volume of dimethylsulfoxide as a second solvent. As an acid compound, hydrochloric acid (HCl) was added to the mixture, thereby obtaining a composition for removing a photoresist. Here, in Examples 9, 10 and 11, compositions for removing a photoresist according to Examples 9, 10 and 11 were prepared by adding the hydrochloric acid at different contents such as 1, 3 and 5 parts by volume.

### Examples 12 to 14

Compositions for removing a photoresist were prepared according to Examples 12 to 14 by the same methods as used in Examples 9 to 11, except that, instead of hydrochloric acid, fluoric acid (HF) was added as an acid compound.

### Examples 15 to 17

Compositions for removing a photoresist were prepared according to Examples 15 to 17 by the same methods as used in Examples 9 to 11, except that, instead of hydrochloric acid, phosphoric acid (H₃PO₄) was added as an acid compound.

### Experimental Example 4: Examination of Photoresist Removal Effect According to Concentration of Acid Compound

Experiments were performed to examine effects of removing a photoresist from a semiconductor substrate when the photoresist is removed using the compositions for removing a photoresist according to Examples 9 to 17.

First, a GaAs wafer coated with an I-line photoresist to a thickness of 1 μm was exposed to an I-line (365 nm) light source using a stepper (Nikon i11D). The exposed photoresist was developed in a DNS SK-200 Coater/Developer. The width and depth of the developed photoresist pattern were 500 nm. Subsequently, using an ICP etcher (multiplexer ICP, STS), the GaAs wafer was dry-etched to have a width of 550 nm and a depth of 500 nm under conditions including BCl₃/N₂ etch gas and a pressure of 0.667 Pa. Afterward, the GaAs wafer was dipped in dimethylsulfoxide at 150° C. for 20 minutes for removing the photoresist and dipped in isopropylalcohol at 30 seconds for cleaning, thereby manufacturing the GaAs wafer patterned in a trench structure. The GaAs wafer patterned in a trench structure was coated with a KrF photoresist (DWK-500, Dongwoo Fine-Chem) to a thickness of 900 nm at 2900 rpm for 60 seconds.

Afterward, P ions were implanted using a medium current ion implanter (E220, Varian) at 30 keV and a pressure of 10⁻⁶ Pa according to condition A (5×10¹³ ions/cm²), condition B (5×10¹⁴ ions/cm²) and condition C (5×10¹⁵ ions/cm²). The GaAs wafers in which ion implantation was performed under conditions A, B and C, respectively, were dipped in the compositions for removing a photoresist according to Examples 1 to 9 and Comparative Example to remove the photoresist. Here, the temperature for the composition for removing a photoresist was 30° C., and the dipping time was 15 minutes. Following dipping, the GaAs wafer was dipped in isopropylalcohol (C₃H₈O, IPA, ≧99.8%, Daejung Chemicals and Metals Co., Ltd) for 30 seconds for cleaning and dried under Na flow.

Following the process of removing a photoresist, the wafers were observed by an optical microscope and an SEM to evaluate the photoresist removal as “X” when the photoresist crust remained, as “Δ” when a photoresist residue remained, and “O” when the photoresist was removed. The evaluation results are shown in Table 1.

TABLE 1

| | | | Dose of ion implantation [ions/cm²] | | |
|---|---|---|---|---|---|
| | Acid compound/added | | Condition A | Condition B | Condition C |
| Example | amount [parts by volume] | | (5 × 10¹³) | (5 × 10¹⁴) | (5 × 10¹⁵) |
| Example9 | hydrochloric | 1 | Δ | Δ | ◯ |
| Example10 | acid | 3 | Δ | Δ | Δ |
| Example11 | | 5 | Δ | Δ | Δ |
| Example12 | fluoric | 1 | ◯ | ◯ | ◯ |
| Example13 | acid | 3 | ◯ | ◯ | ◯ |
| Example14 | | 5 | ◯ | ◯ | Δ |
| Example15 | phosphoric | 1 | Δ | Δ | ◯ |
| Example16 | acid | 3 | Δ | Δ | X |
| Example17 | | 5 | Δ | Δ | X |

As shown in Table 1, in Example 9 in which hydrochloric acid was added as the acid compound, only when the ion implantation dose was 5×10¹⁵ ions/cm² (Condition C), the photoresist was removed. In Examples 12 and 13 in which fluoric acid was added as the acid compound, the photoresist was removed under all ion implantation conditions (Conditions A to C). Also, in Example 15 in which phosphoric acid was added as the acid compound, only when the ion implantation dose was 5×10¹⁵ ions/cm² (Condition C), the photoresist was removed. According to these results, depending on the ion implantation dose, the photoresist removal efficiency may vary, and it is apparent that the preferable acid compound is fluoric acid, and the most preferable amount of the acid compound added herein may be approximately 1 to 3 parts by volume. In Examples 9 to 17, it was confirmed that the photoresist removal efficiency was the same as or higher than that of Example 1 to which an acid compound was not added.

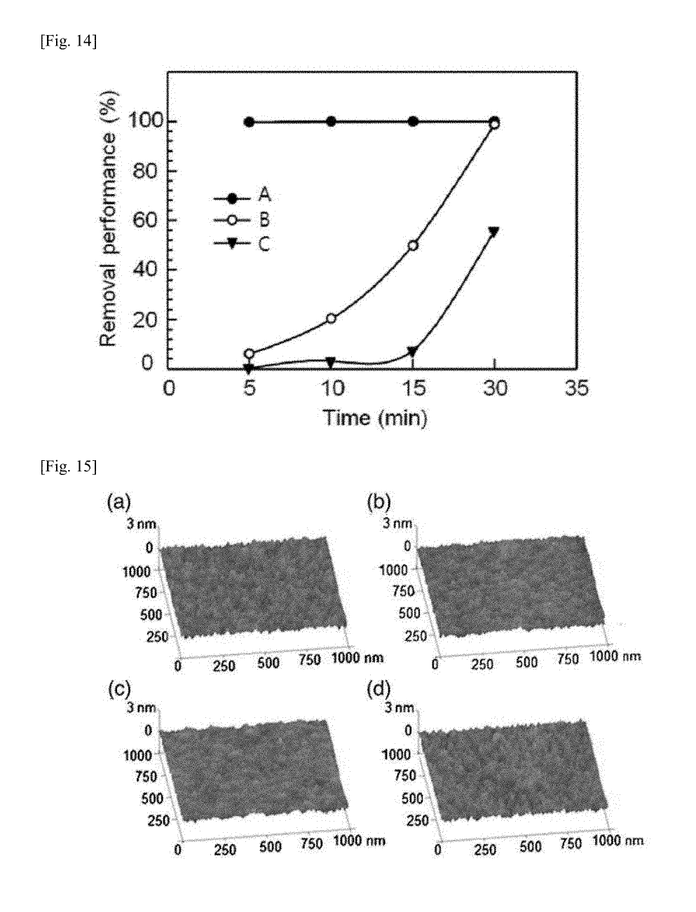

FIG. 16 shows optical microscope images illustrating the result of photoresist removal from the GaAs wafers using the compositions for removing a photoresist according to Examples 9 to 17. Here, a, b and c indicate the cases in which hydrochloric acid, fluoric acid and phosphoric acid were added as acid compounds, respectively, and 1, 3 and 5 represent parts by volume of the acid compounds added to the composition for removing a photoresist, respectively. Referring to FIG. 16, when the acid compound was added at 1 part by volume, regardless of a type of the acid compound, photoresist removal was well performed, and when fluoric acid (a in FIG. 16) was used as the acid compound, the photoresist was removed at all parts by volume.

### Experimental Example 5: Examination of Photoresist Removal Effect According to Temperature of Composition for Removing Photoresist

Experiments were performed to examine the effect of removing a photoresist from a semiconductor substrate according to a temperature of the composition when the photoresist is removed using the compositions for removing a photoresist according to Examples 9 to 17.

First, a GaAs wafer coated with an I-line photoresist to a thickness of 1 μm was exposed to an I-line (365 nm) light source using a stepper (Nikon i11D). The exposed photoresist was developed in a DNS SK-200 Coater/Developer. The width and depth of the developed photoresist pattern were 500 nm. Subsequently, using an ICP etcher (multiplexer ICP, STS), the GaAs wafer was dry-etched to have a width of 550 nm and a depth of 500 nm under conditions including BCl₃/N₂ etch gas and a pressure of 0.667 Pa. Afterward, the GaAs wafer was dipped in dimethylsulfoxide at 150° C. for 20 minutes for removing the photoresist and dipped in isopropylalcohol for 30 seconds for cleaning, thereby manufacturing the GaAs wafer patterned in a trench structure. The GaAs wafer patterned in a trench structure was coated with a KrF photoresist (DWK-500, Dongwoo Fine-Chem) to a thickness of 900 nm at 2900 rpm for 60 seconds.

Afterward, P ions were implanted at a dose of 5×10¹⁵ ions/cm² using a medium current ion implanter (E220, Varian) at 30 keV and a pressure of 10⁻⁶. The ion-implanted GaAs wafers were dipped in the compositions for removing a photoresist according to Examples 9 to 17 to remove the photoresist. Here, the temperature of the composition for removing a photoresist was controlled to 30° C., 50° C., 70° C. and 90° C. in order to examine the extent of photoresist removal according to a temperature. The dipping time was 15 minutes. Following dipping, the GaAs wafer was dipped in isopropylalcohol (C₃H₈O, IPA, ≧99.8%, Daejung Chemicals and Metals Co., Ltd) for 30 seconds for cleaning and dried under Na flow.

Following the process of removing a photoresist, the wafers were observed by an optical microscope and an SEM to evaluate the photoresist removal as “X” when the photoresist layer remained, as “Δ” when a photoresist residue remained, and “O” when the photoresist was removed. The evaluation results are shown in Table 2.

TABLE 2

| | Acid compound/ | | | | | |
|---|---|---|---|---|---|---|
| | added amount | | Temperature of composition for | | | |
| | [parts by | | removing a photoresist [° C.] | | | |
| Example | volume] | | 30 | 50 | 70 | 90 |
| Example9 | hydro- | 1 | ◯ | ◯ | D | D |
| Example10 | chloric | 3 | Δ | D | D | D |
| Example11 | acid | 5 | Δ | D | D | D |
| Example12 | fluoric | 1 | ◯ | ◯ | ◯ | D |
| Example13 | acid | 3 | ◯ | ◯ | Δ | D |
| Example14 | | 5 | X | X | D | D |
| Example15 | phos- | 1 | ◯ | ◯ | D | D |
| Example16 | phoric | 3 | X | D | D | D |
| Example17 | acid | 5 | X | D | D | D |

As shown in Table 2, regardless of the type of the acid compound, when the amount of the acid compound added herein was 1 part by volume, the photoresist removal was well performed at 30° C. and 50° C. When the temperature of the composition for removing a photoresist was 70° C. or more, deformation or damage occurred on most of the semiconductor substrates. According to these results, it was apparent that the most preferable amount of the acid compound added to increase the photoresist removal efficiency is approximately 1 part by volume, and the most preferable temperature of the composition for removing a photoresist is 30 to 50° C.

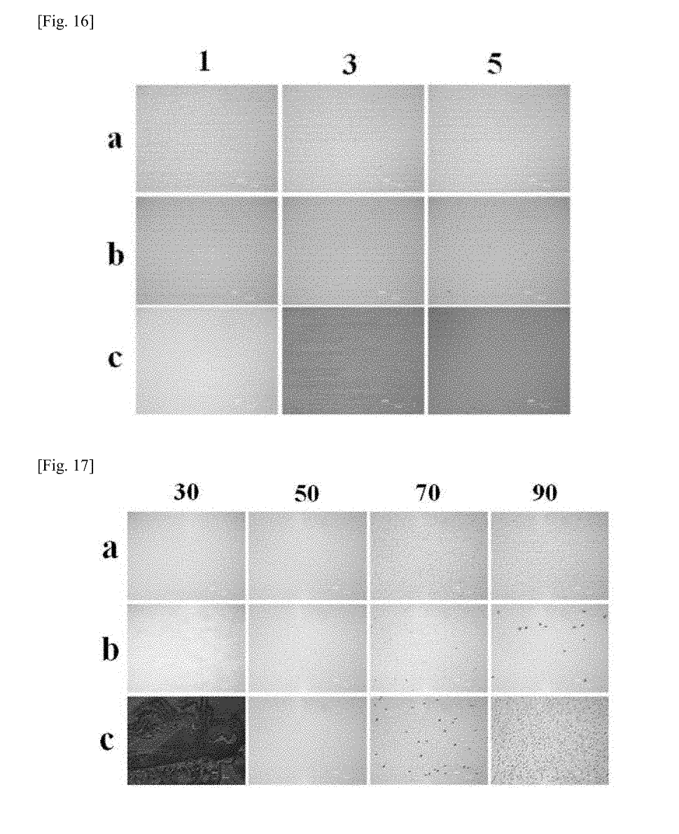

FIG. 17 is an optical microscope image illustrating the result of removing a photoresist from the GaAs wafer into which ions were implanted at 70 keV rather than 30 keV. Here, a, b and c indicate the cases in which hydrochloric acid, fluoric acid and phosphoric acid were added as acid compounds, respectively, and 30, 50, 70 and 90 indicate temperatures of the composition for removing a photoresist. Referring to FIG. 17, when the temperature of the composition for removing a photoresist is 50° C., the photoresist was removed under all conditions for the acid compound, when the temperature was 30° C., the photoresist removal was not performed, and when the temperatures were 70° C. and 90° C., the conductive substrate was deformed or damaged. According to these results, it was apparent that the most preferable temperature for the composition for removing a photoresist to increase the photoresist removal efficiency was approximately 50° C.

A composition for removing a photoresist according to the present invention and a method for removing a photoresist using the same may effectively remove a high-dose ion implanted photoresist without damage, such as etching and oxidation, to a semiconductor substrate. Also, the photoresist removal process can be performed at room temperature and high temperature and thus does not cause deformation with respect to a highly-integrated transistor. Moreover, the present invention can provide a composition for removing a photoresist which can be relatively simply reused due to minimal loss of a solvent by evaporation and may reduce load on equipment, thereby improving the lifespan of the equipment, and a method for removing a photoresist using the same.

It would be understood by those of ordinary skill in the art that the above descriptions of the present invention are exemplary, and the example embodiments disclosed herein can be easily modified into other specific forms without changing the technical spirit or essential features of the present invention. Therefore, it should be interpreted that the example embodiments described above are exemplary in all aspects, and are not limiting.

What is claimed is:

1. A composition for removing a photoresist, comprising:
a first solvent having a molar volume of 70 cm³/mol or less; and
a second solvent having a Hansen relative energy difference from a photoresist of less than 1.05.

2. The composition of claim 1, wherein the first solvent is one or more selected from the group consisting of acetonitrile, formamide, nitromethane and monoethanolamine.

3. The composition of claim 1, wherein the second solvent is one or more selected from the group consisting of methyl-2-pyrrolidone, dimethylsulfoxide, benzylalcohol and propylenecarbonate.

4. The composition of claim 1, wherein the composition for removing a photoresist is a two-liquid type composition comprising a first solution including a first solvent and a second solution including a second solvent.

5. The composition of claim 1, wherein the composition for removing a photoresist comprises an acid compound.

6. The composition of claim 5, wherein the acid compound is one or more selected from the group consisting of fluoric acid (HF), hydrochloric acid (HCl), phosphoric acid (H₃PO₄), tetramethylammoniumhydroxide (TMAT), nitric acid (HNO₃), sulfuric acid (H₂SO₄), oxalic acid and acetic acid.

7. The composition of claim 5, wherein the first solvent is included at 10 to 60 parts by volume, the second solvent is included at 20 to 70 parts by volume, and the acid compound is included at 0.1 to 10 parts by volume.

8. The composition of claim 5, wherein the composition for removing a photoresist is a one-liquid type composition comprising a first solvent, a second solvent and an acid compound.

9. A method for removing a photoresist, comprising:
reacting a semiconductor substrate on which a photoresist is formed with a composition comprising a first solvent having a molar volume of 70 cm³/mol or less, a second solvent having a Hansen relative energy difference from the photoresist of less than 1.05.

10. The method of claim 9, further comprising:
dipping the semiconductor substrate on which the photoresist is formed in a first solution including the first solvent having a molar volume of 70 cm³/mol or less to make the photoresist swell; and
dipping the semiconductor substrate having the swollen photoresist in a second solution including the second solvent having a Hansen relative energy difference from a photoresist of less than 1.05 to remove the photoresist.

11. The method of claim 9, comprising:
reacting a semiconductor substrate on which a photoresist is formed with a composition comprising a first solvent having a molar volume of 70 cm³/mol or less, a second solvent having a Hansen relative energy difference from the photoresist of less than 1.05, and an acid compound.

12. The method of claim 11, wherein the composition comprising the first solvent, the second solvent and the acid compound comprises the first solvent at 10 to 60 parts by volume, the second solvent at 20 to 70 parts by volume, and the acid compound at 0.1 to 10 parts by volume.
